(19) United States
(12) Patent Application Publication
(10) Pub. No.: US 2026/0244910 A1
(43) Pub. Date: Aug. 20, 2026

(54) SPINTRONIC DEVICE, RESERVOIR DEVICE, AND RESERVOIR NEURAL NETWORK ARCHITECTURE

(71) Applicant: INSTITUTE OF MICROELECTRONICS, CHINESE ACADEMY OF SCIENCES, Beijing (CN)

(72) Inventors: Guozhong XING, Beijing (CN); Huai LIN, Beijing (CN); Ziwei WANG, Beijing (CN); Xuefeng ZHAO, Beijing (CN)

(21) Appl. No.: 19/164,255

(22) PCT Filed: Sep. 22, 2023
(86) PCT No.: PCT/CN2023/120595

§ 371 Date: Sep. 11, 2025

(51) Int. Cl. G06N 3/063

(52) U.S. Cl. CPC G06N 3/063

(57) ABSTRACT

The present disclosure provides a spintronic device, a reservoir device, and a reservoir neural network architecture. The spintronic device includes a magnetic domain device and at least two electrodes. The magnetic domain device includes: a substrate; a spin-orbit coupling layer disposed on the substrate; a magnetic layer disposed on the spin-orbit coupling layer; and a barrier layer disposed on the magnetic layer. The electrodes are inserted from a top surface of the magnetic domain device into the substrate and are configured as observation ports of the spintronic device. A complex, stable, and periodically alternating magnetic domain structure is formed under a combined action of Dzyaloshinskii-Moriya interaction and dipole-dipole interaction between the spin-orbit coupling layer and the magnetic layer. When the reservoir device is implemented, upon application of external magnetic field or electrical pulse excitation, a volatile nonlinear response is obtained, thereby enabling a recognition function of a reservoir network.

### CROSS REFERENCE TO RELATED APPLICATION(S)

This application is a National Stage Application of International Application No. PCT/CN2023/120595, filed on Sep. 22, 2023, entitled “SPINTRONIC DEVICE, RESERVOIR DEVICE, AND RESERVOIR NEURAL NETWORK ARCHITECTURE”, the entire content of which is incorporated herein in its entirety by reference.

### TECHNICAL FIELD

The present disclosure relates to the field of magnetic domain wall technology, and more particularly to a spintronic device, a reservoir device, and a reservoir neural network architecture.

### BACKGROUND

The development of artificial intelligence has driven the coordinated advancement of neural networks and their hardware devices, with applications in areas such as pattern recognition and autonomous driving. How to achieve hardware-friendly neural networks that are high-speed and low-power, along with their corresponding hardware devices, has become an important research direction. In reservoir neural networks, a reservoir layer may greatly improve speed and energy efficiency in pattern recognition tasks due to its inherent connectivity and the fact that it does not require additional training.

In the course of implementing the concepts of the present disclosure, the inventors have identified at least the following problems in the related art: related spintronic devices have insufficient overall connectivity complexity, making them inadequate for complex recognition tasks, and a reservoir computing efficiency is not high.

### SUMMARY

In view of the above, embodiments of the present disclosure provide a spintronic device, a reservoir device, and a reservoir neural network architecture.

In an aspect of embodiments of the present disclosure, a spintronic device is provided, including: a magnetic domain device, where the magnetic domain device includes: a substrate; a spin-orbit coupling layer disposed on a top surface of the substrate; a magnetic layer disposed on a top surface of the spin-orbit coupling layer; and a barrier layer disposed on a top surface of the magnetic layer; and at least two electrodes inserted from a top surface of the magnetic domain device into the substrate and configured as observation ports of the spintronic device; where a complex, stable, and periodically alternating magnetic domain structure is formed under a combined action of Dzyaloshinskii-Moriya interaction and dipole-dipole interaction between the spin-orbit coupling layer and the magnetic layer.

According to an embodiment of the present disclosure, the magnetic domain device further includes: a protective layer disposed on a top surface of the barrier layer.

According to an embodiment of the present disclosure, the magnetic layer is made of at least one material selected from CoFeB, CoFe, NiFe, IrMn, GdFeCo, Co, Fe, two-dimensional CrI₃, or Fe₃GeTe₂; and the spin-orbit coupling layer is made of at least one material selected from Pt, W, Ta, Ru, Au, Ir, or Pd.

In another aspect of embodiments of the present disclosure, a reservoir device is provided, including: a magnetic domain device, where one or more spintronic devices are arranged in an array on the magnetic domain device to form the reservoir device; when an external magnetic field excitation is applied to the reservoir device, the magnetic domain device is configured to form different magnetic textures; and in a case of variations in spin-Hall magnetoresistance and anisotropic magnetoresistance associated with the different magnetic textures, the reservoir device is configured to output a nonlinear voltage response.

According to an embodiment of the present disclosure, a magnetic domain structure formed by the spintronic devices is partitioned into a plurality of first magnetic domain regions using a spatial multiplexing technology; and number of physical nodes is increased in at least one of the plurality of first magnetic domain regions to expand a network scale of the reservoir device, and the network scale of the reservoir device is related to a short-term memory capacity of the reservoir device.

According to an embodiment of the present disclosure, when an external magnetic field is applied to the spintronic device, a magnetization direction of the spintronic device is parallel to a direction of an input current, and a resistance of the spintronic device reaches an upper limit of a resistance range; or when no external magnetic field is applied to the spintronic device, the spintronic device relaxes to a complex magnetic domain state, and a generated magnetic domain wall reduces the resistance of the spintronic device.

In another aspect of embodiments of the present disclosure, a reservoir neural network architecture is provided, including: an input layer to which a pulse excitation signal is input; an intermediate reservoir layer, including the spintronic device or the reservoir device, where the intermediate reservoir layer is configured to process the pulse excitation signal to generate a response signal; and an output and recognition layer configured to acquire the response signal, train the response signal, or perform inference on the response signal.

According to an embodiment of the present disclosure, when pulse excitation signals having same magnetic field and different pulses are input to the input layer, the intermediate reservoir layer is configured to generate response signals corresponding to the different pulses of the pulse excitation signals, and the pulse excitation signal includes an electrical excitation signal and a magnetic excitation signal converted from an image pixel or a speech signal.

According to an embodiment of the present disclosure, a magnetic domain structure formed in the intermediate reservoir layer is partitioned into a plurality of second magnetic domain regions using a spatial multiplexing technology, and each of the second magnetic domain regions includes a pulse input terminal; and when the pulse excitation signal is input to the plurality of pulse input terminals, the output and recognition layer is configured to output a time-multiplexed nonlinear response signal.

According to an embodiment of the present disclosure, the time-multiplexed nonlinear response signal constitutes a plurality of virtual nodes; when the output and recognition layer is configured for training, the intermediate reservoir layer is configured to output linearly separable response voltage signals corresponding to different virtual nodes, and the output and recognition layer is configured to perform linear regression training on the response voltage signals to obtain a recognition information corresponding to the response voltage signals; and the reservoir neural network architecture is configured to perform image or speech recognition.

### BRIEF DESCRIPTION OF THE DRAWINGS

The above and other objectives, features, and advantages of the present disclosure will become more apparent from the following description with reference to the accompanying drawings, in which:

FIG. 1 schematically shows a structural diagram of a spintronic device according to an embodiment of the present disclosure;

FIG. 2 schematically shows a diagram A of a nonlinear resistance response of a spintronic device under an in-plane magnetic field sweep according to an embodiment of the present disclosure;

FIG. 3 schematically shows a diagram B of a nonlinear resistance response of a spintronic device under an in-plane magnetic field sweep according to an embodiment of the present disclosure;

FIG. 4 schematically shows a structural diagram of a reservoir device according to an embodiment of the present disclosure;

FIG. 5 schematically shows a diagram of a resistance response of a reservoir device under an external magnetic field pulse according to an embodiment of the present disclosure;

FIG. 6 schematically shows a diagram of reconfigurable characteristics of a reservoir device according to an embodiment of the present disclosure; and

FIG. 7 schematically shows a diagram of a reservoir neural network architecture according to an embodiment of the present disclosure.

### DETAILED DESCRIPTION OF EMBODIMENTS

Embodiments of the present disclosure will be described below with reference to the accompanying drawings. However, it should be understood that these descriptions are merely exemplary and are not intended to limit the scope of the present disclosure. In the following detailed description, numerous specific details are set forth to provide a thorough understanding of embodiments of the present disclosure. It will be apparent, however, that one or more embodiments may be practiced without these specific details. Moreover, descriptions of well-known structures and techniques are omitted to avoid unnecessarily obscuring the concepts of the present disclosure.

The terminology used herein is for the purpose of describing specific embodiments only and is not intended to limit the present disclosure. The terms “include,” “contain,” and similar expressions indicate the presence of stated features, steps, operations, and/or components, but do not preclude the presence or addition of one or more other features, steps, operations, or components.

In the context of the present disclosure, when a layer/element is described as being on the “top surface” of another layer/element, it may be disposed directly on the other layer/element, or there may be intervening layer(s)/element(s) between them. Moreover, if a layer/element is described as being on the “top surface” of another layer/element in one orientation, it may be on the “bottom surface” of the other layer/element when the orientation is reversed.

All terms (including technical and scientific terms) used herein have the meanings commonly understood by those skilled in the art, unless otherwise defined. It should be noted that the terms used herein should be interpreted as having a meaning consistent with the context of the specification and should not be interpreted in an idealized or overly rigid manner.

When expressions such as “at least one of A, B, and C” are used, they should generally be interpreted as commonly understood by those skilled in the art (for example, “a system having at least one of A, B, and C” should be construed to include, but not be limited to, a system having only A, only B, only C, both A and B, both A and C, both B and C, and/or all of A, B, and C.).

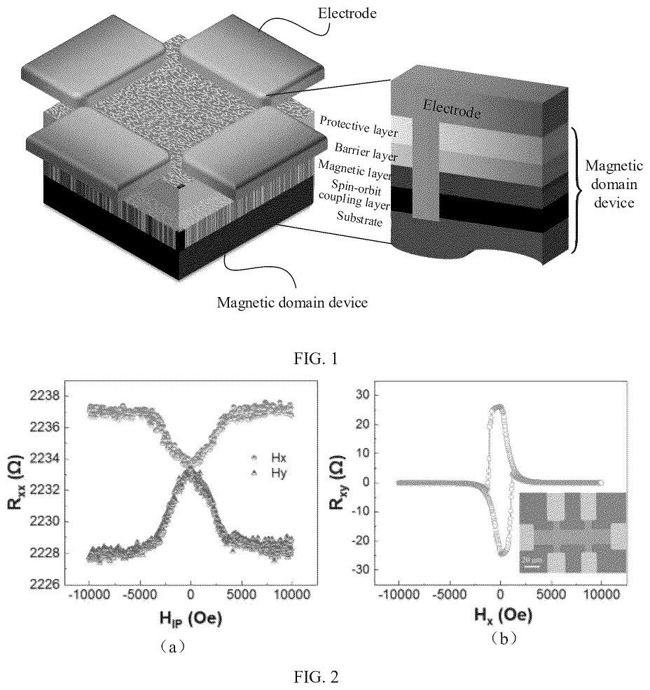

FIG. 1 schematically shows a structural diagram of a spintronic device according to an embodiment of the present disclosure.

According to an embodiment of the present disclosure, as shown in FIG. 1, the spintronic device includes: a magnetic domain device, where the magnetic domain device includes: a substrate; a spin-orbit coupling layer disposed on a top surface of the substrate; a magnetic layer disposed on a top surface of the spin-orbit coupling layer; and a barrier layer disposed on a top surface of the magnetic layer; and at least two electrodes inserted from a top surface of the magnetic domain device into the substrate and configured as observation ports of the spintronic device. A complex, stable, and periodically alternating magnetic domain structure may be formed under a combined action of Dzyaloshinskii-Moriya interaction (DMI) and dipole-dipole interaction between the spin-orbit coupling layer and the magnetic layer.

According to an embodiment of the present disclosure, the magnetic domain structure includes a plurality of magnetic domain regions with random positions, and an interface between two adjacent magnetic domain regions is a magnetic domain wall.

According to an embodiment of the present disclosure, the number of electrodes may be adjusted according to actual requirements, such as 2, 3, 4 or any other integer.

According to an embodiment of the present disclosure, the magnetic domain device further includes: a protective layer disposed on a top surface of the barrier layer.

According to an embodiment of the present disclosure, the magnetic layer is made of at least one material selected from CoFeB, CoFe, NiFe, IrMn, GdFeCo, Co, Fe, two-dimensional CrI₃, or Fe₃GeTe₂, and the protective layer and the spin-orbit coupling layer are made of at least one material selected from Pt, W, Ta, Ru, Au, Ir, or Pd.

According to an embodiment of the present disclosure, the electrodes are made of Ti/Au or Ni/Au, serving as conductive paths and leading out ports. The barrier layer is made of at least one material selected from MgO, AlOₓ, or hBN, and the substrate is a thermally oxidized silicon substrate.

According to an embodiment of the present disclosure, the spintronic device is used as follows.

First, a specific structure of the magnetic layer and the spin-orbit coupling layer may form a complex domain structure stable at room temperature, in which upwardly magnetized and downwardly magnetized magnetic domain structures are periodically and randomly arranged, and magnetic domain walls are generated, forming complex interconnections.

Second, under external in-plane magnetic field excitation, due to the presence of anisotropic magnetoresistance and spin-Hall magnetoresistance, the magnetization of the spintronic device exhibits nonlinear volatile resistance variations. Upon application of a read current, this manifests in the time domain as a nonlinear volatile voltage response of MOKE signals, thereby achieving the functions required by a reservoir neural network system.

Finally, under large in-plane magnetic field resetting, an entirely new magnetic domain structure may be reconfigured, forming a new complex connectivity and thereby achieving a reconfigurable reservoir device.

According to embodiments of the present disclosure, by adjusting the strength of the Dzyaloshinskii-Moriya interaction (DMI), a complex magnetic domain wall stable at room temperature may be formed. Under application of external magnetic field pulse excitation, the resistance changes accordingly, enabling a volatile nonlinear response signal that is related to the history of pulse application. Furthermore, after application of magnetic fields of different magnitudes, an initial resistance signal may be reset, thus forming a reconfigurable reservoir device. The operation method of the basic structural unit of the spintronic device as well as the image recognition function of the corresponding reservoir device are provided, and the spintronic device may be extended to array applications.

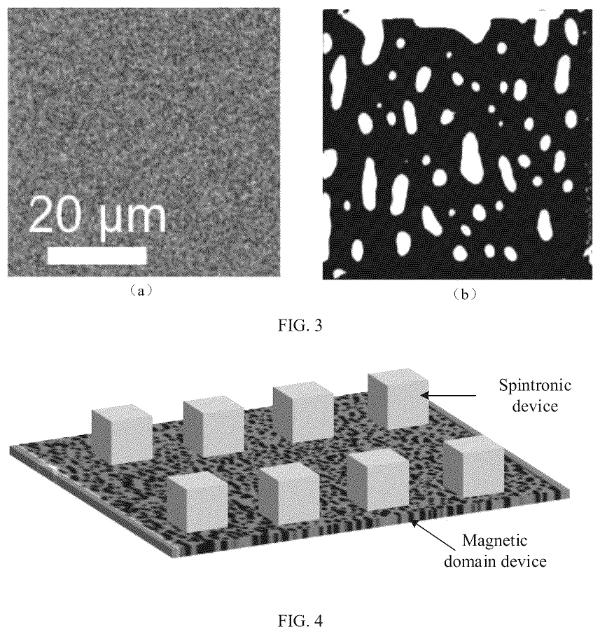

FIG. 2 schematically shows a diagram A of a nonlinear resistance response of a spintronic device under an in-plane magnetic field sweep according to an embodiment of the present disclosure. FIG. 3 schematically shows a diagram B of a nonlinear resistance response of a spintronic device under an in-plane magnetic field sweep according to an embodiment of the present disclosure.

According to an embodiment of the present disclosure, FIG. 2 shows a nonlinear resistance response of a spintronic device under an in-plane magnetic field sweep. (a) of FIG. 2 shows variations in longitudinal resistance Rₓₓ of the spintronic device obtained by sweeping the magnetic field along x-direction and y-direction. When the magnetic field is swept along the x-direction, the resistance increases with the increase in magnetic field magnitude and tends to saturate at about 5000 Oe; as the magnetic field decreases, the resistance returns to its initial value, reflecting the influence of anisotropic magnetoresistance (AMR) on the resistance. When the magnetic field is swept along the y-direction, the resistance decreases with the increase in magnetic field magnitude and tends to saturate at about 5000 Oe; as the magnetic field decreases, the resistance returns to its initial value, reflecting the influence of spin-Hall magnetoresistance (SMR) on the resistance. (b) of FIG. 2 shows that Hall resistance R_{xy} varies with Hₓ, also exhibiting a volatile nonlinear response with a low generalization rank. The above Rₓₓ and R_{xy} may serve as resistances for detection response, and their variations originate from the response of the complex magnetic domain wall structure to the excitation by the external magnetic field. In (a) of FIG. 3, when the in-plane field Hₓ=3000 Oe and the device is saturated, a magnetization direction is fully parallel to the current, and the resistance is at its maximum. In (b) of FIG. 3, when the in-plane field Hₓ=0 Oe and no external magnetic field is applied, the device relaxes to a complex magnetic domain state, and the generated magnetic domain wall reduces the resistance of the spintronic device. The interactions between adjacent magnetizations in the spintronic devices result in the complexity of the reservoir device and provide a high kernel rank.

FIG. 4 schematically shows a structural diagram of a reservoir device according to an embodiment of the present disclosure.

According to an embodiment of the present disclosure, as shown in FIG. 4, the reservoir device includes a magnetic domain device, where one or more spintronic devices are arranged in an array on the magnetic domain device to form the reservoir device. When an external magnetic field excitation is applied to the magnetic domain device, the magnetic domain device forms different magnetic textures. In a case of variations in spin-Hall magnetoresistance and anisotropic magnetoresistance associated with different magnetic textures, the reservoir device outputs a nonlinear voltage response.

According to an embodiment of the present disclosure, when used as a reservoir device, the interaction of spin magnetizations in the spintronic devices is used as a source of complexity to increase the kernel rank of the reservoir device and enhance the capability of the reservoir device to solve complex problems.

According to an embodiment of the present disclosure, a magnetic domain structure formed by the spintronic devices may be partitioned into a plurality of first magnetic domain regions using a spatial multiplexing technology. The number of physical nodes is increased in at least one of the plurality of first magnetic domain regions to expand a network scale of the reservoir device. The network scale of the reservoir device is related to a short-term memory capacity of the reservoir device.

According to an embodiment of the present disclosure, when used as a reservoir device, different magnetic textures are formed under external magnetic field excitation. Due to variations in the spin-Hall magnetoresistance and anisotropic magnetoresistance (SMR/AMR) associated with different magnetic textures, the generalization rank is low, and a nonlinear voltage response may be obtained.

According to embodiments of the present disclosure, when used as a reservoir device, the magnetic domain structure may be partitioned into a plurality of first magnetic domain regions using a spatial multiplexing technology, and the number of physical nodes is increased to expand the network scale of the reservoir device, thereby increasing a memory capacity of the reservoir device and improving a degree of recalling historical input excitations from the current reservoir state.

According to an embodiment of the present disclosure, when an external magnetic field is applied to the reservoir device, a magnetization direction of the reservoir device is parallel to a direction of an input current, and a resistance of the reservoir device reaches an upper limit of a resistance range. When no external magnetic field is applied to the reservoir device, the reservoir device relaxes to a complex magnetic domain state, and a generated magnetic domain wall reduces the resistance of the reservoir device.

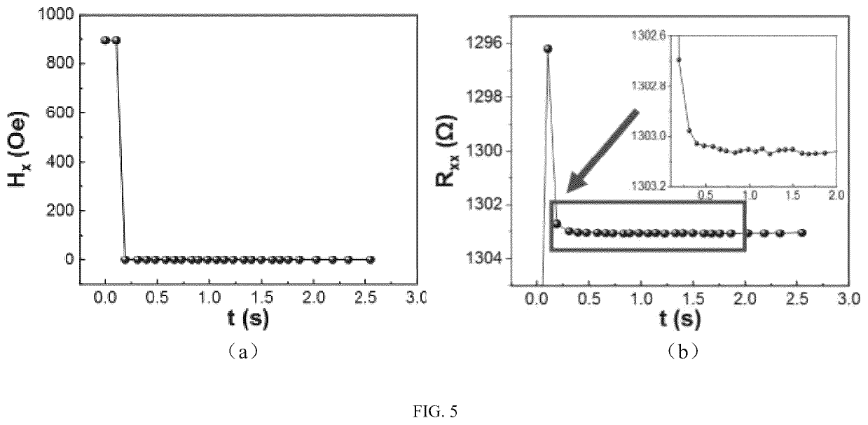

FIG. 5 schematically shows a diagram of a resistance response of a reservoir device under an external magnetic field pulse according to an embodiment of the present disclosure.

According to an embodiment of the present disclosure, (a) of FIG. 5 shows a pulse with a pulse width of 0.1 s and a magnetic field of 900 Oe, and (b) of FIG. 5 shows a response process of the resistance Rₓₓ of the reservoir device. As shown, when the pulse is applied, the resistance changes abruptly, and after the pulse is removed at 0.2 s, the resistance exhibits a nonlinear time-varying response. The time-varying signal may be uniformly sampled, with sampling points serving as virtual nodes to record changes in the pulse history.

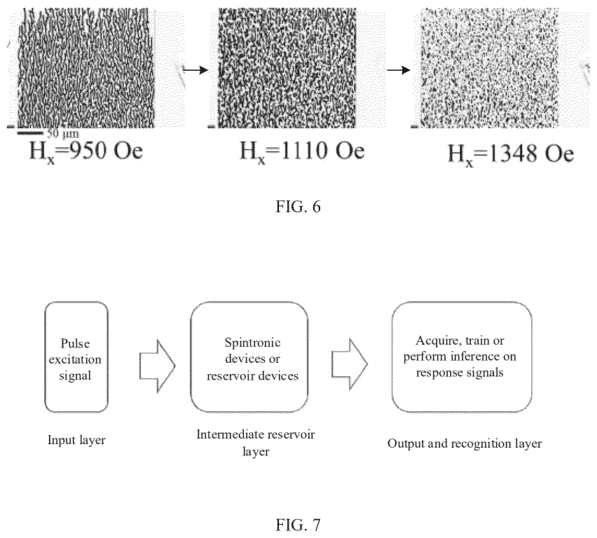

FIG. 6 schematically shows a diagram of reconfigurable characteristics of a reservoir device according to an embodiment of the present disclosure.

According to an embodiment of the present disclosure, FIG. 6 shows the reconfigurable characteristics of the reservoir device. Under excitation of in-plane magnetic field pulses of different magnitudes, the magnetic domains generate periodic arrangements of different densities, and new complex connections are generated between the spins of the magnetic material, thereby forming a new reservoir device. In contrast, under a fixed magnetic field magnitude, the reservoir device has no significant changes. Thus, a reconfigurable reservoir may be achieved. For example, by using magnetic field pulses of different magnitudes, complex magnetic textures under zero field may be reconstructed, and the complex magnetic textures may reset different complex connections to form a new reservoir device.

FIG. 7 schematically shows a diagram of a reservoir neural network architecture according to an embodiment of the present disclosure.

According to an embodiment of the present disclosure, as shown in FIG. 7, the reservoir neural network architecture includes: an input layer to which a pulse excitation signal is input; an intermediate reservoir layer, including the spintronic device or the reservoir device, where the intermediate reservoir layer is configured to process the pulse excitation signal to generate a response signal; and an output and recognition layer configured to acquire the response signal, train the response signal, or perform inference on the response signal.

According to an embodiment of the present disclosure, when pulse excitation signals having same magnetic field and different pulses are input to the input layer, the intermediate reservoir layer is configured to generate response signals corresponding to the different pulses of the pulse excitation signals, and the pulse excitation signal includes an electrical excitation signal and a magnetic excitation signal converted from an image pixel or a speech signal.

According to an embodiment of the present disclosure, a magnetic domain structure formed in the intermediate reservoir layer may be partitioned into a plurality of second magnetic domain regions using a spatial multiplexing technology, and each of the second magnetic domain regions includes a pulse input terminal. When the pulse excitation signal is input to the plurality of pulse input terminals, the output and recognition layer is configured to output a time-multiplexed nonlinear response signal.

According to embodiments of the present disclosure, by partitioning the magnetic domain structure into a plurality of second magnetic domain regions, M pulse input terminals are obtained, thereby forming M physical nodes. After the pulse excitation signal is input, the intermediate reservoir layer generates a time-multiplexed nonlinear response signal, forming N virtual nodes (where M and N are integers, and the specific values depend on reading accuracy), thereby forming a basic intermediate reservoir layer.

According to an embodiment of the present disclosure, the time-multiplexed nonlinear response signal constitutes a plurality of virtual nodes. When the output and recognition layer is used for training, the intermediate reservoir layer may output linearly separable response voltage signals corresponding to different virtual nodes, and the output and recognition layer may perform linear regression training on the response voltage signals to obtain a recognition information corresponding to the response voltage signals. The reservoir neural network architecture is configured to perform image or speech recognition.

According to an embodiment of the present disclosure, during a training process, the response currents of different virtual nodes may be read out, and the corresponding patterns of the current responses of the reservoir device may be obtained through training, thereby achieving image/speech recognition and in-sensor recognition in inference and recognition applications.

According to an embodiment of the present disclosure, FIG. 7 shows a reservoir neural network architecture, which includes an input layer for pulse magnetic fields, an intermediate reservoir layer, and an output and recognition layer. The output and recognition layer is formed by a sequence of pulse magnetic fields. When the reservoir neural network performs recognition tasks, image or speech information is converted into a 0/1 pulse sequence in the input layer. Alternatively, since spintronic devices or reservoir devices may generate direct nonlinear responses under excitation, the input signal (i.e., the pulse excitation signal) may also be an artificial or natural magnetic signal, which is input into the spintronic devices or reservoir devices to serve as a basis for integrated sensing and computing.

According to an embodiment of the present disclosure, the intermediate reservoir layer is formed by spintronic devices having a complex magnetic domain structure, or by an n*n array reservoir devices composed of such spintronic devices. Upon receiving an input pulse excitation signal in the form of a pulse sequence, the intermediate reservoir layer may generate a nonlinear volatile response. During the volatile response period, N virtual nodes (where N is an integer, and the value is related to recognition accuracy and actual task requirements) may be provided to detect and output the response voltage (i.e., the response signal).

According to an embodiment of the present disclosure, a circuit for acquiring, training and performing inference on the response voltage may serve as the output and recognition layer. When a training set information suitable for recognition tasks is input into the intermediate reservoir layer, the spintronic devices or reservoir devices may generate linearly separable voltage outputs. At this point, only linear regression training requires to be performed on the output signals to make the output voltage signals correspond to the desired recognition information (such as digits 0-9 in number or speech recognition). After training is completed, the reservoir neural network system may recognize task sets using the same input method and reservoir computing principle.

According to embodiments of the present disclosure, the spintronic device, the reservoir device, and the reservoir neural network architecture of the present disclosure may achieve the following effects: (1) magnetization switching may reach the nanosecond level, enabling high-speed reservoir computing; (2) the input to the reservoir neural network architecture may be a magnetic signal used as excitation, which means that it may be extended for applications in sensing-memory-computing integrated systems; (3) under large in-plane magnetic field resetting, an entirely new magnetic domain structure may be reconfigured, forming a new complex connectivity and thereby achieving a reconfigurable reservoir device; (4) by increasing the number of physical nodes using spatial multiplexing technology, the number of virtual nodes may be reduced while maintaining the memory capacity of the reservoir device, thereby improving the accuracy of the response signals of the virtual nodes.

The embodiments of the present disclosure have been described above. However, these embodiments are intended only for illustrative purposes and not to limit the scope of the present disclosure. Although the embodiments are described separately above, this does not mean that the measures in each embodiment cannot be advantageously combined. The scope of the present disclosure is defined by the appended claims and their equivalents. Without departing from the scope of the present disclosure, various substitutions and modifications may be made by those skilled in the art, and all such substitutions and modifications should fall within the scope of the present disclosure.

1. A spintronic device, comprising:
a magnetic domain device, wherein the magnetic domain device comprises:
a substrate;
a spin-orbit coupling layer disposed on a top surface of the substrate;
a magnetic layer disposed on a top surface of the spin-orbit coupling layer; and
a barrier layer disposed on a top surface of the magnetic layer; and
at least two electrodes inserted from a top surface of the magnetic domain device into the substrate and configured as observation ports of the spintronic device;
wherein a complex, stable, and periodically alternating magnetic domain structure is formed under a combined action of Dzyaloshinskii-Moriya interaction and dipole-dipole interaction between the spin-orbit coupling layer and the magnetic layer.

2. The spintronic device according to claim 1, wherein the magnetic domain device further comprises:
a protective layer disposed on a top surface of the barrier layer.

3. The spintronic device according to claim 1, wherein:
the magnetic layer is made of at least one material selected from CoFeB, CoFe, NiFe, IrMn, GdFeCo, Co, Fe, two-dimensional CrI₃, or Fe₃GeTe₂; and
the spin-orbit coupling layer is made of at least one material selected from Pt, W, Ta, Ru, Au, Ir, or Pd.

4. A reservoir device, comprising:
a magnetic domain device, wherein one or more spintronic devices according to claim 1 are arranged in an array on the magnetic domain device to form the reservoir device;
wherein when an external magnetic field excitation is applied to the reservoir device, the magnetic domain device is configured to form different magnetic textures, and
wherein in a case of variations in spin-Hall magnetoresistance and anisotropic magnetoresistance associated with the different magnetic textures, the reservoir device is configured to output a nonlinear voltage response.

5. The reservoir device according to claim 4, wherein a magnetic domain structure formed by the spintronic devices is partitioned into a plurality of first magnetic domain regions using a spatial multiplexing technology; and
wherein number of physical nodes is increased in at least one of the plurality of first magnetic domain regions to expand a network scale of the reservoir device, and the network scale of the reservoir device is related to a short-term memory capacity of the reservoir device.

6. The reservoir device according to claim 4, wherein:
when an external magnetic field is applied to the reservoir device, a magnetization direction of the reservoir device is parallel to a direction of an input current, and a resistance of the reservoir device reaches an upper limit of a resistance range; or
when no external magnetic field is applied to the reservoir device, the reservoir device relaxes to a complex magnetic domain state, and a generated magnetic domain wall reduces the resistance of the reservoir device.

7. A reservoir neural network architecture, comprising:
an input layer to which a pulse excitation signal is input;
an intermediate reservoir layer, comprising the spintronic device according to claim 1, wherein the intermediate reservoir layer is configured to process the pulse excitation signal to generate a response signal; and
an output and recognition layer configured to acquire the response signal, train the response signal, or perform inference on the response signal.

8. The reservoir neural network architecture according to claim 7, wherein: when pulse excitation signals having same magnetic field and different pulses are input to the input layer, the intermediate reservoir layer is configured to generate response signals corresponding to the different pulses of the pulse excitation signals, and the pulse excitation signal comprises an electrical excitation signal and a magnetic excitation signal converted from an image pixel or a speech signal.

9. The reservoir neural network architecture according to claim 7, wherein a magnetic domain structure formed in the intermediate reservoir layer is partitioned into a plurality of second magnetic domain regions using a spatial multiplexing technology, and each of the second magnetic domain regions comprises a pulse input terminal; and
wherein when the pulse excitation signal is input to the plurality of pulse input terminals, the output and recognition layer is configured to output a time-multiplexed nonlinear response signal.

10. The reservoir neural network architecture according to claim 9, wherein the time-multiplexed nonlinear response signal constitutes a plurality of virtual nodes;
wherein when the output and recognition layer is configured for training, the intermediate reservoir layer is configured to output linearly separable response voltage signals corresponding to different virtual nodes, and the output and recognition layer is configured to perform linear regression training on the response voltage signals to obtain a recognition information corresponding to the response voltage signals; and
wherein the reservoir neural network architecture is configured to perform image or speech recognition.

11. A reservoir neural network architecture, comprising:
an input layer to which a pulse excitation signal is input;
an intermediate reservoir layer, comprising the reservoir device according to claim 4, wherein the intermediate reservoir layer is configured to process the pulse excitation signal to generate a response signal; and
an output and recognition layer configured to acquire the response signal, train the response signal, or perform inference on the response signal.

12. The reservoir neural network architecture according to claim 11, wherein: when pulse excitation signals having same magnetic field and different pulses are input to the input layer, the intermediate reservoir layer is configured to generate response signals corresponding to the different pulses of the pulse excitation signals, and the pulse excitation signal comprises an electrical excitation signal and a magnetic excitation signal converted from an image pixel or a speech signal.

13. The reservoir neural network architecture according to claim 11, wherein a magnetic domain structure formed in the intermediate reservoir layer is partitioned into a plurality of second magnetic domain regions using a spatial multiplexing technology, and each of the second magnetic domain regions comprises a pulse input terminal; and
wherein when the pulse excitation signal is input to the plurality of pulse input terminals, the output and recognition layer is configured to output a time-multiplexed nonlinear response signal.

14. The reservoir neural network architecture according to claim 13, wherein the time-multiplexed nonlinear response signal constitutes a plurality of virtual nodes;
wherein when the output and recognition layer is configured for training, the intermediate reservoir layer is configured to output linearly separable response voltage signals corresponding to different virtual nodes, and the output and recognition layer is configured to perform linear regression training on the response voltage signals to obtain a recognition information corresponding to the response voltage signals; and
wherein the reservoir neural network architecture is configured to perform image or speech recognition.
